(19) United States
(12) Patent Application Publication
(10) Pub. No.: US 2011/0204409 A1
(43) Pub. Date: Aug. 25, 2011

(54) hBN INSULATOR LAYERS AND ASSOCIATED METHODS

(76) Inventors: Chien-Min Sung, Tansui (TW); Shao Chung Hu, Xindian City (TW); Chien-Chung Teng, Taipei City (TW); Shang-Ray Yang, Taipei City (TW); Michael Sung, Shanghai (CN)

(21) Appl. No.: 13/014,105

(22) Filed: Jan. 26, 2011

Related U.S. Application Data
(60) Provisional application No. 61/298,458, filed on Jan. 26, 2010.

(30) Foreign Application Priority Data
Apr. 27, 2010 (CN) 201010167406.0

(51) Int. Cl. H01L 33/64; C09K 5/08; H05K 1/00; H05K 1/03; H05K 7/20; F28F 7/00

(52) U.S. Cl. 257/99; 252/71; 174/258; 174/255; 174/252; 165/185; 257/E33.075

(57) ABSTRACT

Electrically insulating layers having increased thermal conductivity, as well as associated devices and methods are disclosed. In one aspect, for example, a printed circuit board is provided including a substrate and an electrically insulating layer coated on at least one surface of the substrate, the electrically insulating layer including a plurality of hBN particles bound in a binder material.

### PRIORITY DATA

This application claims the benefit of U.S. Provisional Patent Application Ser. No. 61/298,458, filed on Jan. 26, 2010, which is incorporated herein by reference in its entirety. This application also claims benefit of Chinese Patent Application Serial no. 201010167406.0, filed on Apr. 27, 2010.

### FIELD OF THE INVENTION

The present invention relates generally to hexagonal boron nitride materials in electronic applications. Accordingly, the present invention involves the electrical and material science fields.

### BACKGROUND OF THE INVENTION

In many countries, major portions of the populations consider electronic devices to be integral to their lives. Such increasing use and dependence has generated a demand for electronics devices that are smaller and faster. As electronic circuitry increases in speed and decreases in size, cooling of such devices becomes problematic.

Electronic devices generally contain printed circuit boards having integrally connected electronic components that allow the overall functionality of the device. These electronic components, such as processors, transistors, resistors, capacitors, light-emitting diodes (LEDs), etc., generate significant amounts of heat. As it builds, heat can cause various thermal problems associated with both the printed circuit board and internally in many electronic components. Significant amounts of heat can affect the reliability of an electronic device, or even cause it to fail by, for example, causing burn out or shorting both within the electronic components themselves and across the surface of the printed circuit board. Thus, the buildup of heat can ultimately affect the functional life of the electronic device. This is particularly problematic for electronic components with high power and high current demands, as well as for the printed circuit boards that support them.

The prior art often employs fans, heat sinks, Peltier and liquid cooling devices, etc., as means of reducing heat buildup in electronic devices. As increased speed and power consumption cause increasing heat buildup, such cooling devices generally must increase in size to be effective and also require power in and of themselves to operate. For example, fans must be increased in size and speed to increase airflow, and heat sinks must be increased in size to increase heat capacity and surface area. The demand for smaller electronic devices, however, not only precludes increasing the size of such cooling devices, but may also require a significant size decrease.

### SUMMARY OF THE INVENTION

Accordingly, the present invention provides materials, devices, and methods that provide increased electrical insulation and increased thermal management. In one aspect, for example, a printed circuit board is provided including a substrate and an electrically insulating layer coated on at least one surface of the substrate, the electrically insulating layer including a plurality of hBN particles bound in a binder material.

In another aspect, the present invention provides an electrically insulating layer including a plurality of hBN particles bound in a binder material, wherein thermal conductivity of the electrically insulating layer is greater than or equal to about 5 W/mK.

The plurality of hBN particles can be present in the electrically insulating layer in various amounts, depending on the nature of the binder and the desired properties of the layer. In one aspect, for example, the electrically insulating layer includes the plurality of hBN particles in an amount of about 10 to about 60 vol %. In another aspect, the electrically insulating layer includes the plurality of hBN particles in an amount of less than or equal to about 35 vol %. It should be noted that vol % can be the vol % of the preformed mixture used to form the electrically insulating layer, or it can be the vol % of the finished electrically insulating layer.

Because hBN materials have a planar configuration, other materials can be added to the electrically insulating layer to improve physical and/or thermal contact between hBN particles. In one aspect, for example, contact particles are distributed throughout the electrically insulating layer to provide a thermal pathway between planar faces of the plurality of hBN particles. Any particle that is compatible with hBN and can provide improved thermal contact can be used as a contact particle. In one specific aspect the contact particles are members selected from the group consisting of AlN, diamond, cBN, SiC, Al₂O₃, BeO, SiO₂, and combinations thereof.

Various binder materials are contemplated for use in bonding the hBN particles. It should be noted that such bonding can be chemical or mechanical in nature. In one aspect, the binder material includes a member selected from the group consisting of amino resins, acrylate resins, alkyd resins, polyester resins, polyamide resins, polyimide resins, polyurethane resins, phenolic resins, phenolic/latex resins, epoxy resins, isocyanate resins, isocyanurate resins, polysiloxane resins, reactive vinyl resins, polyethylene resins, polypropylene resins, polystyrene resins, phenoxy resins, perylene resins, polysulfone resins, acrylonitrile-butadiene-styrene resins, acrylic resins, polycarbonate resins, polyimide resins, and combinations thereof. In another aspect, the binder material includes a member selected from the group consisting of AlN, SiC, Al₂O₃, BeO, SiO₂, and combinations thereof.

In another aspect of the present invention, a light-emitting diode device having improved heat dissipation properties is provided having a light-emitting diode thermally coupled to a printed circuit board according to aspects of the present invention, such that the electrically insulating layer is operable to accelerate heat movement away from the light-emitting diode.

In yet another aspect of the present invention, a thermally dynamic printed circuit board device having improved heat dissipation properties is provided having a central processing unit thermally coupled to a printed circuit board according to aspects of the present invention, such that the electrically insulating layer is operable to accelerate heat movement away from the central processing unit.

In yet another aspect, a method for cooling and electrically insulating a printed circuit board is provided. Such a method can include providing a circuit including a heat source, the circuit being disposed on a surface of an electrically insulating layer, the electrically insulating layer including a plurality of hBN particles bound in a binder material, such that upon passing an electrical current through the circuit, heat generated by the circuit is accelerated away from the heat source through the electrically insulating layer at a rate of greater than or equal to 5 W/mK.

The present invention also provides thermal interface materials (TIM). Such materials can include a conformable matrix material and a plurality of hBN particles disposed in the conformable matrix material.

There has thus been outlined, rather broadly, various features of the invention so that the detailed description thereof that follows may be better understood, and so that the present contribution to the art may be better appreciated. Other features of the present invention will become clearer from the following detailed description of the invention, taken with the accompanying claims, or may be learned by the practice of the invention.

### BRIEF DESCRIPTION OF THE DRAWINGS

FIG. 1 is a cross-sectional view of an electronic device in accordance with one embodiment of the present invention.

FIG. 2 is a cross-sectional view of an electronic device in accordance with another embodiment of the present invention.

### DETAILED DESCRIPTION OF THE INVENTION

### Definitions

In describing and claiming the present invention, the following terminology will be used in accordance with the definitions set forth below.

The singular forms “a,” “an,” and, “the” include plural referents unless the context clearly dictates otherwise. Thus, for example, reference to “a particle” includes reference to one or more of such particles, and reference to “the material” includes reference to one or more of such materials.

As used herein, hexagonal boron nitride (hBN) refers to an sp2 bonded hexagonal lattice of BN, similar in structure to graphene. hBN particles can include single hBN layers or stacks of multiple hBN layers. Within each layer, boron and nitrogen atoms are bound by covalent bonds, whereas layers are held together by weak van der Waals forces.

As used herein, “binder” refers to a material used to facilitate the placement of hBN on a substrate or other structure. Thus a binder can be a material that causes chemical or mechanical bonding of hBN to the substrate or structure.

The terms “heat transfer,” “heat movement,” and “heat transmission” can be used interchangeably, and refer to the movement of heat from an area of higher temperature to an area of cooler temperature. It is intended that the movement of heat include any mechanism of heat transmission known to one skilled in the art, such as, without limitation, conductive, convective, radiative, etc.

As used herein, “printed circuit board” and “circuit board” may be used to describe any circuit structure of chips and package level structures of an electrical device. In one aspect, the circuit board may include a substrate, an insulating layer, and conductive traces.

As used herein, “dynamic” or “dynamically” or “thermally dynamic” refers to a characteristic of a material wherein the material is active at transferring energy. Generally, the dynamic material is active at transferring thermal energy.

As used herein, “heat source” refers to a device or object having an amount of thermal energy or heat which is greater than an immediately adjacent region. In printed circuit boards, for example, a heat source can be any region of the board that is hotter than an adjacent region. Heat sources can include devices that produce heat as a byproduct of their operation (hereinafter known as “primary heat sources” or “active heat sources”), as well as objects that become heated by a transfer of heat energy thereto (hereinafter known as “secondary heat sources” or “passive heat sources”). Examples of primary or active heat sources include without limitation, CPU's, electrical traces, LED's, etc. Examples of secondary or passive heat sources include without limitation, heat spreaders, heat sinks, etc.

As used herein, “conductive trace” refers to a conductive pathway on a printed circuit board or other electronic device that is capable of conducing heat, electricity, or both.

As used herein, “deposited” and “depositing,” refers to an area along at least a portion of an outer surface of a substrate that has been intimately contacted with a material being deposited. In some aspects, the deposited material may be a layer which substantially covers an entire surface of the substrate. In other aspects, the deposited material may be a layer which covers only a portion of a surface of the substrate.

As used herein, “conformable” refers to a material that has the capacity to conform to the shape of a surface upon which it is applied. In the case of Thermal Interface Materials, a conformable material is one that, when disposed between two opposing surfaces, maximizes contact between those surfaces.

As used herein, the term “substantially” refers to the complete or nearly complete extent or degree of an action, characteristic, property, state, structure, item, or result. For example, an object that is “substantially” enclosed would mean that the object is either completely enclosed or nearly completely enclosed. The exact allowable degree of deviation from absolute completeness may in some cases depend on the specific context. However, generally speaking the nearness of completion will be so as to have the same overall result as if absolute and total completion were obtained. The use of “substantially” is equally applicable when used in a negative connotation to refer to the complete or near complete lack of an action, characteristic, property, state, structure, item, or result. For example, a composition that is “substantially free of” particles would either completely lack particles, or so nearly completely lack particles that the effect would be the same as if it completely lacked particles. In other words, a composition that is “substantially free of” an ingredient or element may still actually contain such item as long as there is no measurable effect thereof.

As used herein, the term “about” is used to provide flexibility to a numerical range endpoint by providing that a given value may be “a little above” or “a little below” the endpoint.

As used herein, a plurality of items, structural elements, compositional elements, and/or materials may be presented in a common list for convenience. However, these lists should be construed as though each member of the list is individually identified as a separate and unique member. Thus, no individual member of such list should be construed as a de facto equivalent of any other member of the same list solely based on their presentation in a common group without indications to the contrary.

Concentrations, amounts, and other numerical data may be expressed or presented herein in a range format. It is to be understood that such a range format is used merely for convenience and brevity and thus should be interpreted flexibly to include not only the numerical values explicitly recited as the limits of the range, but also to include all the individual numerical values or sub-ranges encompassed within that range as if each numerical value and sub-range is explicitly recited. As an illustration, a numerical range of “about 1 to about 5” should be interpreted to include not only the explicitly recited values of about 1 to about 5, but also include individual values and sub-ranges within the indicated range. Thus, included in this numerical range are individual values such as 2, 3, and 4 and sub-ranges such as from 1-3, from 2-4, and from 3-5, etc., as well as 1, 2, 3, 4, and 5, individually. This same principle applies to ranges reciting only one numerical value as a minimum or a maximum. Furthermore, such an interpretation should apply regardless of the breadth of the range or the characteristics being described.

The Invention

The present invention relates to novel materials that exhibit increased thermal conductivity without sacrificing desirable electrically insulative properties. These materials utilize hexagonal boron nitride (hBN) as an electrically insulating material. hBN is a planar material having good electrical resistivity, and can thus form sp2 networks similar in structure to graphite. Due to this planar nature, hBN can form face-to-face contacts between planar faces, thus facilitating improved thermal conductivity even at low hBN concentrations in a composite layer. In contrast, non-planar AlN particles disposed in epoxy exhibit fewer contact points between particles due to their blocky structure. As such, thermal conductivity is more limited for such non-planar materials. Moreover, hBN materials can be compressed to improve contacts between faces.

In one aspect of the present invention, an electrically insulating layer is provided. Such a layer can include a plurality of hBN particles bound in a binder material. In one aspect, the thermal conductivity of the electrically insulating layer is greater than or equal to about 5 W/mK. In another aspect, the thermal conductivity of the electrically insulating layer is greater than or equal to about 7.5 W/mK. In yet another aspect, the thermal conductivity of the electrically insulating layer is greater than or equal to about 10 W/mK. Thus the electrically insulating layer can effectively accelerate heat movement away from heat sources or other hot spots, while at the same time providing an electrically resistive layer or surface.

The electrically insulating layers according to aspects of the present invention can be applied to any surface where thermal conductivity is desired. The electrically insulating layers can additionally be applied to surfaces, structures, or devices where thermal conductivity and electrical resistivity is desired. For example, an electrically insulating layer can be applied to an electronic device, such as a printed circuit board or printed circuit. In one aspect, a printed circuit board can include a substrate and an electrically insulating layer coated on at least one surface of the substrate. The electrically insulating layer includes a plurality of hBN particles bound in a binder material. Thus a printed circuit board can be effectively cooled by accelerated heat transfer laterally across the surface of the board and accelerated heat transfer to the air as the heat spreads laterally.

It should be noted that any form of heat source known to introduce heat into a printed circuit board or other electronic device that is known to one skilled in the art is considered to be within the scope of the present invention. In one aspect the heat source can be an active heat source, an example of which may be a heat-generating electronic component. Such components may include, without limitation, resistors, capacitors, transistors, processing units including central and graphics processing units, LEDs, laser diodes, filters, etc. Heat sources can also include regions of a printed circuit board containing a high density of conductive traces, and regions receiving transmitted heated from a heat source that is not in physical contact with the printed circuit board. They can also include heat sources in physical contact with, but not considered integral to the printed circuit board. An example of this may be a motherboard having a daughterboard coupled thereto, where heat is transferred from the daughterboard to the motherboard.

Irrespective of the source, the transfer of heat present in the printed circuit board can be accelerated away from the heat source through the hBN material in the electrically insulating. It should be noted that the present invention is not limited as to specific theories of heat transmission. As such, in one aspect the accelerated movement of heat away from the heat source can be at least partially due to heat movement laterally through the hBN particles. Due to the heat conductive properties of hBN materials, heat can rapidly spread laterally through the electrically insulating layer and across the surface of the printed circuit board. Such accelerated heat transfer can result in printed circuit boards with much cooler operational temperatures.

The acceleration of heat transfer away from a heat source not only cools the printed circuit board, but also may reduce the heat load on many electronic components that are cooled primarily to the air surrounding the printed circuit board. For example, a central processing unit (CPU) having an external heat sink and fan may require less external cooling due to the improved heat transmission through the printed circuit board via the CPU socket.

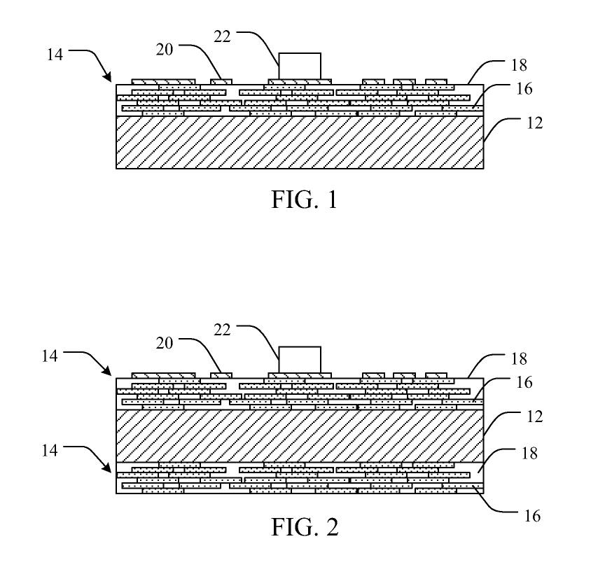

For example, FIG. 1 shows a circuit board having a substrate 12, upon which an electrically insulating layer 14 is deposited. The electrically insulating layer 14 includes a plurality of hBN 16 particles coupled to the substrate 12 by a binder 18. As example heat sources, FIG. 1 shows conductive traces 20 and a CPU package 22 disposed on the electrically insulating layer 14. Thus the electrically insulating layer 14 provides electrical insulation to the heat sources, by preventing current leakage to the substrate 12 and/or to neighboring circuit elements. Additionally, heat generated by the heat sources is conducted to the hBN particles 16 and spread laterally through the electrically insulating layer 14 to improve the dissipation of heat.

As has been described, the electrically insulating layer is a layer of hBN particles and a binder. The electrically insulating layer can be coated on various portions of a printed circuit board or other electronic device, depending on factors such as the intended use of the circuit board, potential temperatures the circuit board may attain, manufacturing costs, etc. The electrically insulating layer can be coated on a portion, one side, or both sides of a printed circuit board. The electrically insulating layer can be disposed on an entire surface, or upon only a portion of a surface. For example, the electrically insulating layer may be disposed on substantially the entire surface of the substrate over which the circuit is disposed. This may be particularly critical where conductive materials such as metals are used for the substrate. Also, an additional electrically insulating layer can be disposed on an opposite surface of the substrate from the primary electrically insulating layer, as is shown in FIG. 2.

The hBN particles can be of any practical size, depending on the manufacturing conditions of the hBN particles and material availability. Provided sufficiently large hBN “sheets” are available, in one aspect the size of the hBN material could substantially match the size of the surface being coated with the electrically insulating layer, or be configured to cover half, one fourth, etc., of the surface size. In another aspect, the hBN particles can be less than 1000 microns. In another aspect, the hBN particles can be from about 1 micron to about 100 microns. In yet another aspect, the hBN particles can be from about 1 micron to about 50 microns. In a further aspect, the hBN particles can be from about 5 microns to about 30 microns. It should be noted that, due to the planar nature of hBN materials, the sizes indicated herein are the approximate average size of the facial plane. The size of the hBN particles perpendicular to the facial plane can vary, depending on the number of hBN layers that are stacked to create the particle. hBN particles having from 1 to many thousands of layers should be included in the present scope.

In some aspects, a bimodal size distribution of hBN particles can be beneficial. Thus two, or in some cases at least two, size distributions of particles are present in the formulation. Larger hBN particles, on the order of 10 microns for example, have good thermal conductivity but may limit the adhesive strength of the binder in the formulation. Smaller particles are more readily incorporated into the binder, thus allowing greater surface contact and increased adhesive strength. The increase grain boundaries around the smaller hBN particles, however, may tend to decrease the thermal conductivity. The inventors have discovered that a bimodal size distribution of larger particles mixed with smaller particles can facilitated increase thermal conductivity and increase adhesive strength. Although any bimodal size distribution that results in enhanced thermal conductivity and increased adhesive strength would be considered to be within the present scope, in one aspect the bimodal size distribution includes a first hBN particle size of from about 5 microns to about 15 microns and a second hBN particle size of from about 1 micron to about 3 microns. In another aspect, the bimodal size distribution includes a first hBN particle size of about 10 microns and a second hBN particle size of about 2 microns. In yet another aspect, a first hBN particle size is at least about 2 times greater than a second hBN particle size. It should be noted that this effect may also be observed with formulations having more than two size distributions of hBN particles, and as such, are considered to be within the present scope. Also, these improved effects due to the bimodal size distribution can occur across material types. For example, in one aspect larger hBN particles (e.g. 10 microns) can be mixed into the binder with smaller diamond particles (e.g. 2 microns).

The electrically insulating layer can include the plurality of hBN particles in a variety of proportions relative to the total volume of the layer. The planar nature of the hBN particles allow the use of lower proportions of hBN, however, this does not preclude layers having a majority of the constituent material being hBN. Thus the electrically insulating layer can contain hBN in any amount to obtain a desirable or intended result. In one specific aspect, however, the electrically insulating layer includes the plurality of hBN particles in an amount of from about 10 to about 60 vol %. In another specific aspect, the electrically insulating layer includes the plurality of hBN particles in an amount of less than or equal to about 40 vol %. In yet another specific aspect, the electrically insulating layer includes the plurality of hBN particles in an amount of less than or equal to about 30 vol %. In another specific aspect, the electrically insulating layer includes the plurality of hBN particles in an amount of less than or equal to about 20 vol %. In another specific aspect, the electrically insulating layer includes the plurality of hBN particles in an amount of less than or equal to about 10 vol %. It should be noted that increasing the proportion of hBN in the binder material increases the potential number of thermal contacts, thus increasing the thermal conductivity of the electrically insulating layer. It should also be noted that vol % can be the vol % of the preformed mixture used to make the electrically insulating layer, or it can be the vol % of the finished electrically insulating layer.

Due to the planar nature of the hBN particles, a binder can be used to bond the hBN particles to each other and to a substrate. Numerous binders are contemplated, and thus can vary depending on the desired or intended result for the electrically insulating layer. The use of binder materials having electrical insulative properties can function in conjunction with the hBH materials to prevent current leakage. Though any known binder material may be used, examples may include, without limitation, inorganic materials, polymeric materials, and the like, including combinations thereof. In one aspect, non-limiting examples of useful inorganic binders may include, for example, Al₂O₃, MgO, BeO, ZnO, SiO₂, AlN, SiC, and the like, including combinations thereof. In one specific aspect, the inorganic binders may include Al₂O₃. In another specific aspect, the inorganic binder can include AlN. In another aspect, non-limiting examples of inorganic binders may include, without limitation, Li₂O—Al₂O₃—SiO₂ based materials, MgO—Al₂O₃—SiO₂ based materials, Li₂O—MgO—SiO₂ based materials, Li₂O—ZnO—SiO₂ based materials, and combinations thereof.

In another aspect, the hBN particles can be disposed in a polymeric binder. Once the hBN particles are mixed with the polymeric binder, the composite mixture can be applied to a surface for curing. Such application can occur by any known means, including, without limitation, spraying, spreading, dipping, and the like. Non-limiting examples of polymeric binders includes materials such as amino resins, acrylate resins, alkyd resins, polyester resins, polyamide resins, polyimide resins, polyurethane resins, phenolic resins, phenolic/latex resins, epoxy resins, isocyanate resins, isocyanurate resins, polysiloxane resins, reactive vinyl resins, polyethylene resins, polypropylene resins, polystyrene resins, phenoxy resins, perylene resins, polysulfone resins, acrylonitrile-butadiene-styrene resins, acrylic resins, polycarbonate resins, polyimide resins, and combinations thereof. In one specific aspect, the polymeric binder can be an epoxy resin. In another specific aspect, the polymeric binder can be a polyamide resin. In yet another specific aspect, the binder can be benzocyclobutene.

Furthermore, the thickness of the electrically insulating layer can be variable, depending on the intended use of the material and/or the device upon which it is deposited. In one aspect, however, the electrically insulating layer can be from about 100 μm thick to about 2000 μm thick. In another aspect, the electrically insulating layer can be from about 10 μm thick to about 100 μm thick. In yet another aspect, the electrically insulating layer can be less than or equal to 200 μm thick. In another aspect, the electrically insulating layer can be greater than 200 μm thick.

As has been described, the electrically insulating layer material is utilized to couple the hBN particles to a substrate in order to provide electrical isolation to a circuit disposed thereon, while at the same time effectively conducting heat. As such, a variety of substrate materials may be utilized to form the structure of a circuit board or other electrical device substrate, regardless of the substrate material's conductive properties. For example, the substrate may be a metal material such as aluminum. By disposing a circuit onto the electrically insulating layer, substrate materials such as metals can be utilized in the construction of various electronic devices. In addition to metals, a variety of ceramic and polymeric materials can be used as substrates. Such materials are well known in the art, and may vary depending on the nature and intended use of the circuit board.

Due to the planar nature of hBN materials, non-planar particles can be added to the electrically insulating layer in order to improve thermal contact between the hBN particles. The addition of such “contact particles” can cause the planar hBN materials to bend or buckle, thus improving thermal contact by providing a thermal pathway between planar faces of the plurality of hBN particles. Any thermally conductive material that is compatible with the hBN particles and the binder can be utilized as contact particles. In one aspect the contact particles can be a ceramic powder or particles. Specific non-limiting examples of contact particles include AlN, diamond, cBN, SiC, Al₂O₃, BeO, SiO₂, and the like, including combinations thereof. The proportion of contact particles added to the mixture can vary depending on the desired thermal conductivity of the resulting electrically insulating layer. In one aspect, the proportion of contact particles in the layer is less than the vol % of the hBN particles in the layer. In another aspect, the proportion of contact particles in the layer is from about 1 to about 20 vol %. In yet another aspect, the proportion of contact particles in the layer is less than about 15 vol %. It should be noted that vol % can be the vol % of the preformed mixture used to make the electrically insulating layer, or it can be the vol % of the finished electrically insulating layer. Additionally, in one aspect the contact particles can have size in the range of from about 0.1 to about 20 microns. In another aspect the contact particles can have size in the range of from about 1 to about 15 microns.

It may also be beneficial in some cases to utilize contact particles and/or hBN particles that include a miscibility agent to affect the solubility of the particles in the binder. In one aspect, one end of the miscibility agent is hydrophilic while the other end is lipophilic or hydrophobic. As one example, N or O atoms at a terminal end of a miscibility agent tend to render the agent hydrophilic at that end. As another example, H or F atoms at a terminal end of a miscibility agent tend to render the agent hydrophobic at that end. Thus such miscibility agents can improve the solubility of such particles in a given binder, reducing agglomeration and helping to spread the particles out within the binder. In one non-limiting example, a miscibility agent can include vinyl silane, amino silane, and combinations thereof. Other non-limiting examples can include oleyl alcohol polyethylene glycol ether, oleyl alcohol ethoxylate, octyl phenol ethoxylate, polyethylene glycol, 2-butanone, 4-methyl-2-ketone, acetone, N,N-dimethylformamide, and the like. Additionally, because hBN is intrinsically hydrophobic, it can be boiled in nitric acid or hydrosulfuric acid to attach NO or SO radicals to the surface. Thus by incorporating such miscibility agents to the hBN surface the uniform mixing into various binders can be facilitated.

In some aspects hBN particles can be confined in a layer separate or substantially separate from other materials. For example, in one aspect a layer of hBN particles in a binder can be arranged adjacent to a layer of another material in a binder such as a ceramic powder. In some aspects such an adjacent ceramic particle layer can penetrate into the hBN layer to improve heat dissipation of heat by increasing the thermal conductivity between hBN planes.

In some aspects, thermal conduction can be increased by intercalating metal atoms within the hBN particles. Non-limiting examples of such metal atoms include Li, Na, K, Be, Mg, Ca, and the like, including combinations thereof. Metal atoms can also be incorporated as oxides, nitrides, or other molecular compounds that improve the thermal conduction of the hBN material. Specific non-limiting examples can include Li₂O and the like, and Li₃N and the like. Such metal atoms can be introduced during the formation of the hBN particles by, for example, doping, or the metal atoms can be infiltrated into the hBN particles following formation. Although any amount of metal atoms are considered to be within the present scope, in one aspect the hBN particles include at least about 1 at. % of metal atoms.

In some aspects, a fiber cloth can be included in the electrically insulating layer to improve the electrical resistivity of the layer. The inclusion of such a fiber cloth layer can be used in a variety of situations. In one non-limiting example, such a cloth can be included in electrically insulating layers used for high breakdown voltage situations where electrical safety is a concern. The hBN particles can block the holes between the fibers to improve electrical resistivity as compared to the cloth in a binder without the hBN particles. If fiberglass cloth is used, heat can effectively be conducted through the holes between the fibers through a thermal pathway created by the hBN materials.

It is contemplated that a variety of heat sources may be cooled according to various aspects of the present invention. For example, the heat source may be a central or graphics processing unit, an LED, a laser diode, a filter such as a surface acoustic wave filter, etc. In one aspect, for example, an LED device having improved heat dissipation properties may be provided. Such a device may include a light-emitting diode thermally coupled to a circuit of a device. As such, the electrically insulating layer is configured to accelerate heat movement away from the light-emitting diode. As they have become increasingly important in electronics and lighting devices, LEDs continue to be developed that have ever increasing power requirements. This trend of increasing power has created cooling problems for these devices. These cooling problems can be exacerbated by the typically small size of these devices, which may render heat sinks with traditional aluminum heat fins ineffective due to their bulky nature. By cooling an LED according to aspects of the present invention, adequate cooling even at very high power can be achieved, while maintaining a small LED package size.

As one specific example, in one aspect a light-emitting diode device having improved heat dissipation properties is provided, including a light-emitting diode thermally coupled to a printed circuit board as described, such that the electrically insulating layer is operable to accelerate heat movement away from the light-emitting diode. In another aspect, thermally dynamic printed circuit board device having improved heat dissipation properties is provided, including a central processing unit thermally coupled to a printed circuit board as described, such that the electrically insulating layer is operable to accelerate heat movement away from the central processing unit.

In addition, the present invention provides methods for using the described electrically insulative layers. In one aspect, for example, a method for cooling and electrically insulating a printed circuit board is provided. Such a method can include providing a circuit including a heat source, where the circuit is disposed on a surface of an electrically insulating layer. The electrically insulating layer includes a plurality of hBN particles bound in a binder material, such that upon passing an electrical current through the circuit, heat generated by the circuit is accelerated away from the heat source through the electrically insulating layer at a rate of greater than or equal to 5 W/mK.

Various methods of depositing electrically insulative layers onto a substrate are also contemplated, and may vary depending on the binder material. For example, in one aspect the plurality of hBN particles can be mixed with a binder material. This may be particularly effective using a polymeric binder. Subsequently, the mixture is disposed onto the substrate to form the electrically insulative layer. Such deposition can be accomplished by a variety of methods known to those of ordinary skill in the art, including knife casting, spraying, dipping, rolling, tape casting, etc. The binder material can be allowed to harden, or it can be heated or reacted with a catalyst, depending on the nature of the material. In a similar aspect, hBN particles can be deposited onto the substrate and a binder material can be disposed thereon. In such a case, a mold may be beneficial to hold the hBN particles and the binder material during application and curing.

Certain materials, particularly inorganic materials such as AlN and the like, can be sequentially deposited or co-deposited with the hBN particles. Such deposition of the inorganic material can include sintering, sputtering, melt spraying (e.g. flame spray, plasma spray), mixing, spreading, etc.

It is also contemplated that the electrically insulating layer can be a Thermal Interface Material (TIM). Such materials are often used to improve the thermal contact between two materials in a thermal dissipation pathway. One example is the use of TIM between a CPU and a CPU fan to facilitate the movement of heat from the CPU to the fan. Similarly, TIM can be used between any heat source and an associated heat sink.

In one aspect, a TIM can include a conformable matrix material having a plurality of hBN particles disposed therein. The conformable material can also be referred to as a binder or solvent. The conformable matrix can include any conformable material that is capable of containing the hBN particles and is compatible with the surfaces between which it is to be used. Conformable matrix materials are well known in the art, and can include materials such as thermal greases. In one specific aspect, the conformable matrix material can include a liquid or gelatinous silicone compound (e.g. “silicone paste” or “silicon oil”). In some cases, the conformable matrix material may be electrically conductive, provided that adequate electrical insulation is utilized to electrically insulate against short circuits occurring between the surfaces.

As has been described, the conformable matrix material can also include non-planar contact particles in order to improve thermal contact between the hBN particles. The addition of such “contact particles” can cause the planar hBN materials to bend or buckle, thus improving thermal contact by providing a thermal pathway between planar faces of the plurality of hBN particles.

### EXAMPLE

### Example 1

hBN is mixed with an organic binder that is dissolved in an organic solvent. The slurry is spray coated onto an aluminum substrate cured to remove solvent. The resulting layer is an approximately 50 micron thick insulating layer that can spread heat. This electrically insulating layer is sputtered with Cr and electroplated with Cu. The Cu is then etched to form circuit elements. An LED chip is then mounted on the substrate and electrically coupled to the circuit elements. The LED chip is cooled by the electrically insulating layer that conducts heat to the aluminum substrate.

### Example 2

hBN is mixed with SnO₂ nanopowder and then plasma sprayed onto an aluminum substrate. The hBN/SnO₂ layer has improved thermal conductivity as it does not contain an organic binder. This electrically insulating layer is then sputtered with Cr and electroplated with Cu, and the Cu is etched to form circuit elements.

### Example 3

A 24 inch (610 mm)×18 inch (457 mm) Metal Core Printed Circuit Board (MCPCB) is made by laminating a 70 micron thick epoxy resin on a 2 mm thick aluminum substrate (1050, 5052 or 6061) and 50 micron thick copper foil. The epoxy resin is premixed with 65 wt % of solid content which contains 80:20 of Al₂O₃ (1-2 micron grain size) and hBN powder so that the weight of the hBN accounts for 13% of the total weight. The MCPCB is then tested for peel strength and thermal conductivity. When the hBN particle size is 10 microns, K value is 4 W/mk and the peeling strength is 6 lbs/in². When the hBN particle size is 2 microns, the k value is 3.5 W/mK and the peeling strength is 9 lbs/in². When a mixture of hBN sizes is used (2 microns and 10 microns at 3:1), the K value is 4.5 W/mk and the peeling strength is 8 lbs/in².

### Example 4

Epoxy resin is mixed with a silane based coupling agent to a viscosity of 9500 cps. hBN particles are combined with the mixture, followed by dilution with methyl ethyl ketone solvent. During the mixing process, Al₂O₃ powder is mixed into the methyl ethyl ketone solvent and also the epoxy curing agent. A fiber cloth is impregnated with the resulting mixture and the composite material is cured for 90 seconds at 170° C. The composite material is heat laminated between Cu and Al to form a PCB.

### Example 5

50 wt % of 10 μm hBN particles and 5 wt % of 2 μm diamond particles are dispersed in a silica gel. The hBN and diamond particles have been previously treated at 800° C. for 30 minutes in a hydrogen environment in order to absorb hydrogen atoms to facilitate dispersion in the silica gel. The thermal conductivity of the above treated silica gel is approximately 4 W/mK.

### Example 6

2 μm hBN powder and 1 μm diamond powder are mixed with about 3 wt % of an acrylic grease to form a dough. The dough is shaped, extruded, and sliced in 100 μm thick sections. A thin layer of acrylic grease is sprayed onto an aluminum substrate and a 100 μm section is placed thereon. A 30 μm thick copper foil is then applied to the 100 μm section. The resulting layered composite is formed into an MCPCB using a laminator. The thermal conductivity of this laminated structure is between about 5-10 W/mK due to plurality of hBN and diamond powder contained in the insulation layer between aluminum substrate and copper foil.

Of course, it is to be understood that the above-described arrangements are only illustrative of the application of the principles of the present invention. Numerous modifications and alternative arrangements may be devised by those skilled in the art without departing from the spirit and scope of the present invention and the appended claims are intended to cover such modifications and arrangements. Thus, while the present invention has been described above with particularity and detail in connection with what is presently deemed to be the most practical and preferred embodiments of the invention, it will be apparent to those of ordinary skill in the art that numerous modifications, including, but not limited to, variations in size, materials, shape, form, function and manner of operation, assembly and use may be made without departing from the principles and concepts set forth herein.

What is claimed is:

1. A printed circuit board, comprising:
a substrate; and
an electrically insulating layer coated on at least one surface of the substrate, the electrically insulating layer including a plurality of hBN particles bound in a binder material.

2. The printed circuit board of claim 1, wherein the electrically insulating layer includes the plurality of hBN particles in an amount of from about 10 to about 60 vol %.

3. The printed circuit board of claim 1, wherein the electrically insulating layer includes the plurality of hBN particles in an amount of less than or equal to about 40 vol %.

4. The printed circuit board of claim 1, wherein thermal conductivity of the electrically insulating layer is greater than or equal to about 5 W/mK.

5. The printed circuit board of claim 1, comprising a plurality of contact particles distributed throughout the electrically insulating layer such that the contact particles provide a thermal pathway between planar faces of the plurality of hBN particles.

6. The printed circuit board of claim 5, wherein the contact particles are members selected from the group consisting of AlN, diamond, cBN, SiC, Al₂O₃, BeO, SiO₂, and combinations thereof.

7. The printed circuit board of claim 1, wherein the binder material includes a member selected from the group consisting of amino resins, acrylate resins, alkyd resins, polyester resins, polyamide resins, polyimide resins, polyurethane resins, phenolic resins, phenolic/latex resins, epoxy resins, isocyanate resins, isocyanurate resins, polysiloxane resins, reactive vinyl resins, polyethylene resins, polypropylene resins, polystyrene resins, phenoxy resins, perylene resins, polysulfone resins, acrylonitrile-butadiene-styrene resins, acrylic resins, polycarbonate resins, polyimide resins, and combinations thereof.

8. The printed circuit board of claim 1, wherein the binder material includes a member selected from the group consisting of AlN, SiC, Al₂O₃, BeO, SiO₂, and combinations thereof.

9. The printed circuit board of claim 1, wherein the substrate is a metal material.

10. The printed circuit board of claim 1, wherein the substrate is a ceramic material.

11. The printed circuit board of claim 1, wherein the substrate is a polymeric material.

12. The printed circuit board of claim 1, wherein the electrically insulating layer includes a fiber cloth material.

13. The printed circuit board of claim 1, wherein the hBN particles are planar particles.

14. A light-emitting diode device having improved heat dissipation properties, comprising:
a light-emitting diode thermally coupled to the printed circuit board of claim 1, such that the electrically insulating layer is operable to accelerate heat movement away from the light-emitting diode.

15. A thermally dynamic printed circuit board device having improved heat dissipation properties, comprising:
a central processing unit thermally coupled to the printed circuit board of claim 1, such that the electrically insulating layer is operable to accelerate heat movement away from the central processing unit.

16. An electrically insulating layer, comprising a plurality of hBN particles bound in a binder material, wherein thermal conductivity of the electrically insulating layer is greater than or equal to about 5 W/mK.

17. The electrically insulating layer of claim 16, wherein the electrically insulating layer includes the plurality of hBN particles in an amount of from about 10 to about 60 vol %.

18. The electrically insulating layer of claim 16, wherein the electrically insulating layer includes the plurality of hBN particles in an amount of less than or equal to about 40 vol %.

19. The electrically insulating layer of claim 16, comprising a plurality of contact particles distributed throughout the electrically insulating layer such that the contact particles provide a thermal pathway between planar faces of the plurality of hBN particles.

20. The electrically insulating layer of claim 16, wherein the hBN particles have a bimodal size distribution.

21. The electrically insulating layer of claim 20, wherein the bimodal size distribution includes a first hBN particle size of from about 5 microns to about 15 microns and a second hBN particle size of from about 1 micron to about 3 microns.

22. The electrically insulating layer of claim 20, wherein the bimodal size distribution includes a first hBN particle size of about 10 microns and a second hBN particle size of about 2 microns.

23. A method for cooling and electrically insulating a printed circuit board, comprising:
providing a circuit including a heat source, the circuit being disposed on a surface of an electrically insulating layer, the electrically insulating layer including a plurality of hBN particles bound in a binder material, such that upon passing an electrical current through the circuit, heat generated by the circuit is accelerated away from the heat source through the electrically insulating layer at a rate of greater than or equal to 5 W/mK.

24. A thermal interface material, comprising:
a conformable matrix material;
a plurality of hBN particles disposed in the conformable material.

25. The thermal interface material of claim 24, comprising a plurality of contact particles distributed throughout the conformable matrix material such that the contact particles provide a thermal pathway between planar faces of the plurality of hBN particles.

26. The thermal interface material of claim 25, wherein the contact particles are members selected from the group consisting of AlN, diamond, cBN, SiC, Al₂O₃, BeO, SiO₂, and combinations thereof.

27. The thermal interface material of claim 25, wherein the contact particles are ceramic.

28. The thermal interface material of claim 24, wherein the hBN particles contain at least about 1 at. % of a metal.

29. The thermal interface material of claim 28, wherein the metal includes a member selected from the group consisting of Li, Na, K, Be, Mg, Ca, and combinations thereof.
